(19) United States
(12) Patent Application Publication
(10) Pub. No.: US 2023/0080936 A1
(43) Pub. Date: Mar. 16, 2023

(54) Aerosol Generation Device

(71) Applicant: JT International SA, Geneva (CH)

(72) Inventor: Ernst Hupkes, Kampen (NL)

(73) Assignee: JT International SA, Geneva (CH)

(21) Appl. No.: 17/801,584

(22) PCT Filed: Feb. 23, 2021
(86) PCT No.: PCT/EP2021/054451

§ 371 Date: Aug. 23, 2022

(30) Foreign Application Priority Data
Feb. 28, 2020 (EP) 20160270.3

(51) Int. Cl. A24F 40/57; A24F 40/46; A24F 40/60; A24F 40/90; H05K 1/11; H05K 1/14; H05K 1/02

(52) U.S. Cl. CPC A24F 40/57; A24F 40/46; A24F 40/60; A24F 40/90; H05K 1/11; H05K 1/14; H05K 1/028

(57) ABSTRACT

An aerosol generation device includes an electrical power source; a heating chamber operable to heat an aerosol substrate to generate an aerosol; first control circuitry configured to control the supply of electrical power from the electrical power source to the heating chamber; and a housing comprising a mouth end and an opposing end. The electrical power source, the heating chamber and the first control circuitry are arranged in an internal volume of the housing, the heating chamber being arranged between the first control circuitry and the mouth end, and the first control circuitry being arranged between the heating chamber and the electrical power source.

### TECHNICAL FIELD

The present disclosure relates to an aerosol generation device. The disclosure is particularly applicable to a portable aerosol generation device, which may be self-contained and low temperature. Such devices may heat, rather than burn, tobacco or other suitable aerosol substrate materials by conduction, convection, and/or radiation, to generate an aerosol for inhalation.

### BACKGROUND

The popularity and use of reduced-risk or modified-risk devices (also known as vaporisers) has grown rapidly in the past few years as an aid to assist habitual smokers wishing to quit smoking traditional tobacco products such as cigarettes, cigars, cigarillos, and rolling tobacco. Various devices and systems are available that heat or warm aerosolisable substances as opposed to burning tobacco in conventional tobacco products.

A commonly available reduced-risk or modified-risk device is the heated substrate aerosol generation device or heat-not-burn device. Devices of this type generate an aerosol or vapour by heating an aerosol substrate that typically comprises moist leaf tobacco or other suitable aerosolisable material to a temperature typically in the range 150° C. to 300° C. Heating an aerosol substrate, but not combusting or burning it, releases an aerosol that comprises the components sought by the user but not the toxic and carcinogenic by-products of combustion and burning. Furthermore, the aerosol produced by heating the tobacco or other aersolisable material does not typically comprise the burnt or bitter taste resulting from combustion and burning that can be unpleasant for the user and so the substrate does not therefore require the sugars and other additives that are typically added to such materials to make the smoke and/or vapour more palatable for the user.

Such devices commonly comprise a heating chamber for heating the aerosol substrate, and an electrical power source for supplying power to the heating chamber. The electrical power source is usually either disposable or rechargeable, so that the lifetime of the device is not limited by the single energy storage capacity of the electrical power source. The heating chamber is typically required to heat quickly, for relatively short amounts of time, which means that it is desirable to be able to supply high power to the heating chamber, and it is desirable to supply the power efficiently.

Such devices are commonly hand-held, and are preferably easy to grip and safe to hold on their exterior even while heating the aerosol substrate. It is therefore desirable to provide a device which can be easily and safely hand-held.

Additionally, it is desirable to provide a device which performs heating efficiently, such that the user is only required to replace or recharge the electrical power source infrequently.

### SUMMARY

According to a first aspect, the present disclosure provides an aerosol generation device comprising: an electrical power source; a heating chamber operable to heat an aerosol substrate to generate an aerosol; first control circuitry configured to control the supply of electrical power from the electrical power source to the heating chamber; and a housing comprising a mouth end and an opposing end, wherein the electrical power source, the heating chamber and the first control circuitry are arranged in an internal volume of the housing, the heating chamber being arranged between the first control circuitry and the mouth end, and the first control circuitry being arranged between the heating chamber and the electrical power source.

By arranging the contents of the housing according to the invention, a cross-section of the device can be reduced and the device can more easily fit in the hand of a user. Additionally, by arranging the control circuitry between the electrical power source and the heating chamber, a length of electrical connections from the electrical power source to the heating chamber can be reduced. Resistive losses in the electrical connections can thereby also be reduced, and heating efficiency can be improved.

Optionally, the mouth end, the heating chamber, the first control circuitry and the electrical power source are arranged along a common line. By arranging all of the heating chamber, first control circuitry and electrical power source in a line extending through the mouth end, the device has a linear configuration which can be made as narrow as possible and made easier again to hold.

Optionally, the first control circuitry comprises a first PCB. By providing a first PCB as part of the first control circuitry, the control circuitry can be prepared as a single component which can be simply assembled into the device.

Optionally, the first PCB is arranged in a plane transverse to the common line. With this arrangement, the first PCB takes up little space along the first direction. Given that circuitry components are generally small relative to power sources and heating chambers in aerosol generation devices, this arrangement helps to efficiently fit the components of the device into as small a housing as possible. Additionally, with this arrangement, the first PCB can provide heat shielding between the heating chamber and the electrical power source.

Optionally, the first PCB comprises electrical contacts for connections to the electrical power source and electrical contacts for connections to the heating chamber. By providing electrical contacts to both of the electrical power source and the heating chamber on a single PCB, the connection length for relatively high power between the electrical power source and the heating chamber can be reduced, and power for other lower power components can be diverted within the PCB away from the high power connection.

Optionally, on a surface of the first PCB, a first electrical contact for the electrical power source is adjacent to a first electrical contact for the heating chamber and a second electrical contact for the electrical power source is adjacent to a second electrical contact for the heating chamber. By arranging first and second terminals for the heating chamber respectively next to first and second terminals for the electrical power source, the distance of high power transfer within the first PCB can be reduced, which reduces the heat dissipated in the first PCB.

Optionally, the first PCB is a double-sided PCB, and the electrical contacts for connections to the electrical power source are arranged on one side of the double-sided PCB and the electrical contacts for connections to the heating chamber are arranged on the other side of the double-sided PCB. With this arrangement, wire connections do not need to extend around the first PCB, and the first PCB can extend across the internal space of the housing to divide the internal space in two, a first part of the internal space containing the electrical power source, and a second part of the internal space containing the heating chamber.

Optionally, in the first PCB, a first electrical contact for the electrical power source is directly connected to a first electrical contact for the heating chamber or a second electrical contact for the electrical power source is directly connected to a second electrical contact for the heating chamber. With this arrangement, the required number of independent electrical contacts is reduced, and manufacture of the first PCB can be simplified.

Optionally, the first PCB is arranged as a thermal barrier between the heating chamber and the electrical power source. With this arrangement, heat leaking from the heating chamber is less likely to reach the electrical power source, and the maximum temperature of the electrical power source in use is reduced, improving safety.

Optionally, the device further comprises a heating chamber frame configured to support the heating chamber, and a power source frame configured to support the electrical power source. By providing a frame for each of the heating chamber and the electrical power source, the heating chamber and the electrical power source can be located at a fixed position within the device, and prevented from moving within the device, reducing the risk of damage when the device is, for example, dropped.

Optionally, the first control circuitry is supported between the heating chamber frame and the power source frame. With this arrangement, the first control circuitry is also located in a fixed position within the device, without increasing complexity by adding a third frame feature.

Optionally, the device further comprises second control circuitry, wherein the first control circuitry is configured to support a higher power than the second control circuitry, the first control circuitry being configured to communicate with the second control circuitry using logical signalling. By providing different control circuitry supporting different power levels, components which are not needed for carrying power between the electrical power source and the heating chamber can be constructed from less durable (and less costly) materials than if all control circuitry in the device used similar materials.

Optionally, the second control circuitry is configured to control the first control circuitry. With this configuration, all of the “intelligent” control circuitry (such as a logical processor) can be constructed from relatively low power circuitry, with the controlled first control circuitry simply providing basic power supply management and switching.

Optionally, the second control circuitry comprises a second PCB. By providing a second PCB as part of the second control circuitry, the second control circuitry can be prepared as a single component which can be simply assembled into the device.

Optionally, the second PCB is connected to the first PCB by a flexible PCB portion. With this arrangement, the complete control circuitry can be assembled into the device simply by bending the flexible PCB portion to achieve required positions of the first and second PCBs, and the electrical connections between the first and second PCBs are confined to a small volume.

Optionally, the second control circuitry is arranged alongside the heating chamber. By arranging the second control circuitry alongside the heating chamber, a risk of exposure to gases vented from the electrical power source is reduced.

Optionally, the heating chamber frame is arranged as a thermal barrier between the heating chamber and the second control circuitry. With this arrangement, a maximum temperature of the second control circuitry in use is reduced, and the second control circuitry can be constructed from materials with a lower temperature tolerance.

According to a second aspect, the present disclosure provides control circuitry for an aerosol generation device comprising an electrical power source and a heating chamber operable to heat an aerosol substrate to generate an aerosol, the control circuitry comprising: a first PCB configured to control the supply of electrical power from the electrical power source to the heating chamber, wherein the first PCB comprises electrical contacts for connections to the electrical power source and electrical contacts for connections to the heating chamber; and a second PCB, wherein the first PCB is configured to support a higher power than the second PCB, the first PCB being configured to communicate with the second PCB using logical signalling.

Optionally, the second PCB is connected to the first PCB by a flexible PCB portion.

Optionally, the first PCB is a double-sided PCB comprising contacts on both sides.

Optionally, the second PCB comprises a main logical board configured to perform central control of the rest of the control circuitry.

Optionally, the control circuitry comprises a third PCB which is a user interface board.

Optionally, the control circuitry comprises a fourth PCB comprising a charging board through which power may be supplied to recharge the electrical power source.

Optionally, the control circuitry comprises a fifth PCB which comprises a Hall sensor.

Optionally, the second PCB is connected to the first, third, fourth and fifth PCBs by flexible portions.

In aerosol generation devices, the power supplied from the electrical power source to a heating element (such as a heating chamber) is much larger than power used for other circuitry such as user interfaces, and timing circuits. By providing control circuitry in the form of a higher-power PCB configured to transfer power between the electrical power source and the heating chamber and a lower-power PCB configured to communicate with the higher-power PCB using logical signalling, the size of a PCB for controlling power can be minimized and the path length (and resistive losses) for driving the heating chamber can be minimized, while also providing PCB space which can be used for lower-power systems such as a processor providing logical control of the aerosol generation device.

### BRIEF DESCRIPTION OF THE DRAWINGS

FIG. 1 is a schematic illustration of an aerosol generation device according to the invention;

FIG. 2 is a schematic illustration of a first partially assembled state of the aerosol generation device;

FIGS. 3A and 3B are schematic illustrations of a second partially assembled state of the aerosol generation device;

FIGS. 4A and 4B are schematic illustrations of a third partially assembled state of the aerosol generation device;

FIG. 5 is a schematic illustration of a fourth partially assembled state of the aerosol generation device;

FIGS. 6A and 6B are schematic illustrations of first and second sides of control circuitry of the aerosol generation device.

### DETAILED DESCRIPTION

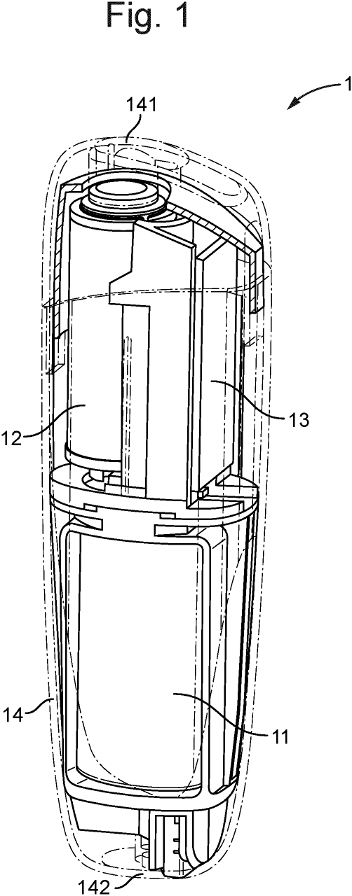

FIG. 1 is a schematic illustration of an aerosol generation device 1 according to the invention.

The device 1 comprises an electrical power source 11, a heating chamber 12, and control circuitry 13 all of which are arranged in an internal volume of a housing 14.

The electrical power source 11 may, for example, be a battery such as a dry battery or a pouch battery.

The heating chamber 12 is a chamber having a heater operable to supply heat into the chamber to heat an aerosol substrate therein, and generate an aerosol. For example, the heating chamber 12 may comprise a ceramic or metal cylindrical wall, open at one end, and surrounded by an insulator. An open end of the heating chamber 12 is preferably oriented with a mouth end 141 of the housing. In other embodiments, the device 1 may comprise tubing to transfer a generated aerosol from the heating chamber 12 to the mouth end 141 of the housing. The heating chamber 12 receives electrical power to drive the heater. For example, the heater may be a resistive heater, such as a resistive track that is either attached to the chamber or located inside or around the chamber wall, or a blade heater that protrudes into the chamber and is operable to penetrate into the aerosol substrate.

The control circuitry 13 is configured to control the supply of electrical power from the heating chamber. The control circuitry may be as simple as a manual switch that can be operated by the user. However, the control circuitry is preferably complex enough to regulate the power supply to provide a required heating rate in the heating chamber, for example using a buffer, a booster and/or an amplifier. The control circuitry may also perform other functions such as sensing a charge state of the electrical power source 11, recharging the electrical power source 11, providing automatic control of the heating chamber 12 to provide a predetermined amount or strength of aerosol according to user inputs, and controlling output elements (such as LEDs) to indicate a status of the device. Each of the heating chamber 12 and the electrical power source 11 may be directly connected to the control circuitry 13 or may be connected via wires and/or rigid tabs. Tab connections may comprise, for example, steel, nickel or nickel-plated steel.

The housing 14 comprises the mouth end 141 at which generated aerosol is provided for a user to inhale. For example, the mouth end 141 may comprise an opening and a lid. The lid may, for example, be a hinged lid, detachable lid, or a sliding lid as shown in FIG. 1. In other embodiments, the mouth end 141 may be open to allow the aerosol to leave the device 1.

The housing 14 further comprises an opposing end 142 opposing the mouth end 141. As shown in FIG. 1, the housing 14 may be relatively long and narrow between the mouth end 141 and the opposing end 142. With this shape, a user can easily hold the device 1 on the long and narrow sides, in order to place an aerosol substrate in the heating chamber 12 via the mouth end 141 or to bring the mouth end 141 to the user’s mouth to inhale the aerosol generated in the heating chamber 12 via the mouth end 141.

The housing 14 is illustrated as transparent in FIG. 1, for the purpose of showing internal components of the device 1. The housing 14 may be transparent in some embodiments, but this is not essential. In fact, in preferred embodiments, the housing 14 comprises a metal, such as aluminium, for robustness, and consequentially the housing is not transparent. An exterior surface of the housing 14 may be partially or completely covered with a thermal insulator, such as a polymer grip, such that the device 1 can be held by a user even if heat from the heating chamber 12 partly dissipates in the housing 14.

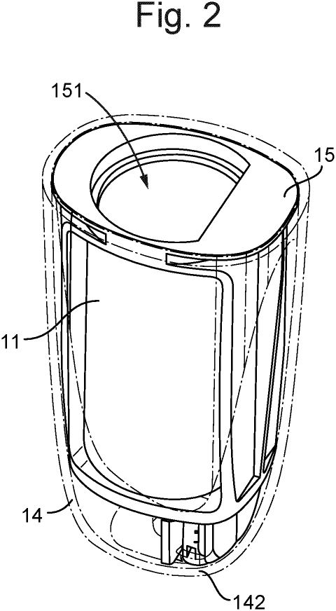

FIG. 2 is a schematic illustration of a first partially assembled state of the aerosol generation device. This is an illustration of only part of the device 1, and need not be a stage in all methods of assembling the device 1.

As shown in FIG. 2, in the embodiment of the figures, the electrical power source 11 is supported by a power source frame 15, in a fixed position in a part of the housing 14 that is towards the opposing end 142. The power source frame 15 is preferably made from a thermally insulating material, such as PEEK (polyether ether ketone).

The power source frame 15 comprises an opening 151 through which electrical connections to the electrical power source 11 can extend. Apart from the opening 151, the power source frame 15 preferably closely conforms to an inner surface of the housing 14 such that the electrical power source 11 is largely shielded by the power source frame 15 from heat in a part of the housing 14 that is towards the mouth end 141.

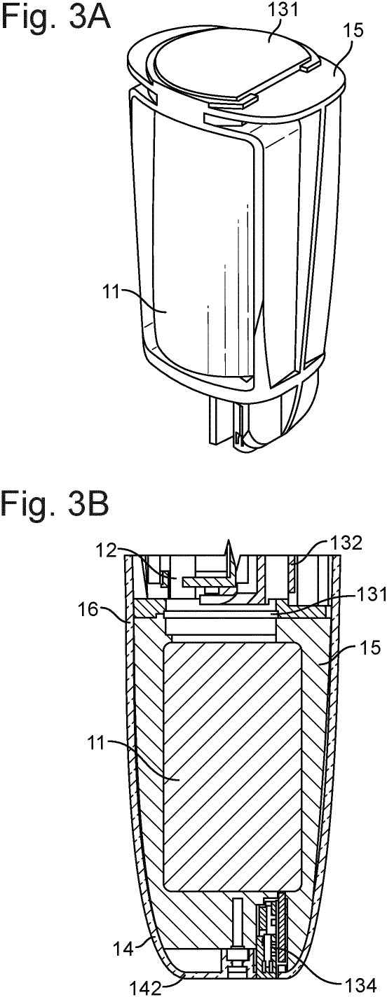

FIG. 3A is a schematic illustration of a second partially assembled state of the aerosol generation device. Again these are illustrations of only part of the device 1, and need not be a stage in all methods of assembling the device 1.

As shown in FIG. 3A, a first control circuitry 131 of the control circuitry 13 is a first PCB. By comparing FIG. 3A to FIG. 1, it can be seen that the first PCB is arranged in a plane transverse to the “long” direction of the housing 14 between the mouth end 141 and the opposing end 142. In this position, the first PCB acts as a thermal barrier between the heating chamber 12 and the electrical power source 11. Together with the power source frame 15, the first PCB 131 can be arranged to provide a complete barrier across the interior of the housing 14. Additionally, in the partially-assembled state shown in FIG. 3A, connections to the first PCB 131 may be easily soldered onto a mouth end-facing side of the first PCB 131.

The complete barrier can be further seen in FIG. 3B, which is a cross-section of the device 1. In FIG. 3B, it is shown that the first PCB 131 is supported between the power source frame 15 and a heating chamber frame 16. The heating chamber frame 16 also supports the heating chamber 12 in a fixed position within the housing 14. The heating chamber frame 16 is preferably made from a thermally insulating material, such as PEEK (polyether ether ketone).

With the power source frame 15 and the heating chamber frame 16, the heating chamber 12 is arranged between the first control circuitry 131 of the control circuitry 13 and the mouth end 141, and the first control circuitry 131 is arranged between the heating chamber 12 and the electrical power source 11.

Preferably, the mouth end 141, the heating chamber 12, the first control circuitry 131 and the electrical power source 11 are arranged along a common line between the mouth end 141 and the opposing end 142. With this arrangement, the device 1 has a linear configuration which can be made as narrow as possible and made easier to hold.

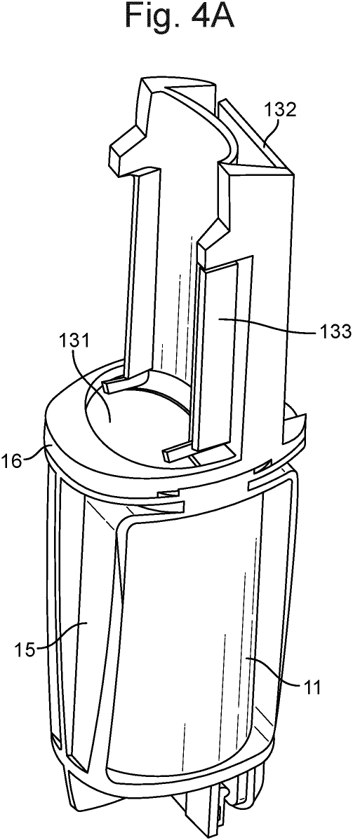

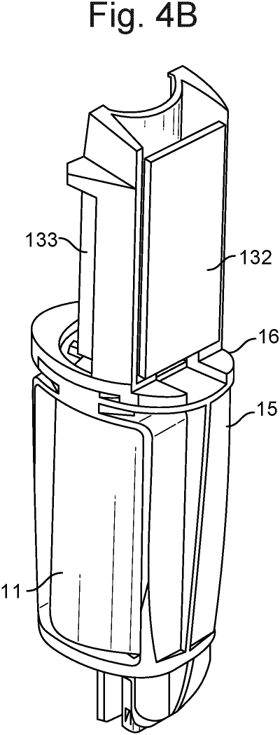

FIGS. 4A and 4B are schematic illustrations of a third partially assembled state of the aerosol generation device. Again these are illustrations of only part of the device 1, and need not be a stage in all methods of assembling the device 1.

In the third partially assembled state, the device 1 additionally has the heating chamber frame 16, second control circuitry 132 and third control circuitry 133. Each of the second control circuitry 132 and third control circuitry 133 may take the form of a PCB as shown in FIGS. 4A and 4B.

As with the power source frame 15, in the embodiment of the figures, the heating chamber frame 16 has an opening through which electrical connections to the electrical power source 11 can extend, for example from the first control circuitry 131.

The heating chamber frame 16 may be an extension of the power source frame 15, and the frames 15 and 16 may be moulded as a single component. In such an embodiment, the opening in the power source frame part 15 or the heating chamber frame part 16 may be large enough to add the first PCB 131 in its assembled position, or the single frame 15, 16 may comprise a side slot for positioning the first PCB 131. Connections to the heating chamber 12 and the electrical power source 11 may be added before or after the first PCB is positioned within the single frame 15, 16.

The second control circuitry 132 in the embodiment of the figures is configured to support a lower power than the first control circuitry 131, and the first control circuitry 131 is configured to communicate with the second control circuitry 132 using logical signalling. More specifically, while the first control circuitry 131 is configured to supply power to the heating chamber, the second control circuitry 132 does not carry a comparable amount of power and only uses power to drive logical circuits such as a processor and a memory. Adaptations to carry larger amounts of power may include thicker wires, wider PCB circuit tracks, inclusion of a heat sink, and other techniques known to the skilled person. Additionally, given the above described secondary function of the first PCB 131 as a heat shield, the first PCB may be thicker than a corresponding second PCB 132 in order to provide improved heat shielding.

The second control circuitry 132 may be configured to control the first control circuitry 131. This has the advantage that all logical control can be moved to the second control circuitry 132, while the first control circuitry 131 only needs to perform the actual handling of power between the electrical power source 11 and the heating chamber 12. In many embodiments, the first control circuitry 131 also provides a power supply for other elements of the control circuitry 13, which may be diverted from the power supply to the heating chamber 12.

The second control circuitry 132 is arranged alongside the heating chamber 12. More specifically, the second control circuitry 132 in the embodiment of the figures is arranged alongside the heating chamber frame 16, such that the heating chamber frame 16 acts as a thermal barrier between the heating chamber 12 and the second control circuitry 132.

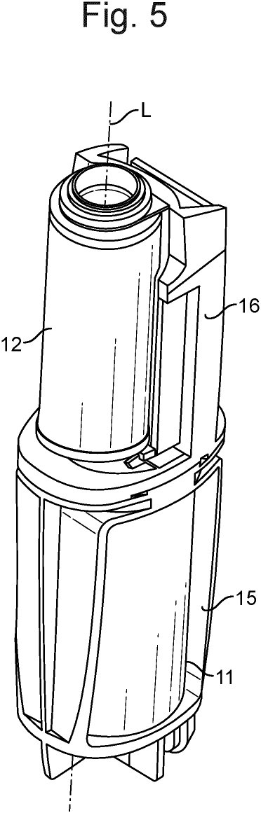

FIG. 5 is a schematic illustration of a fourth partially assembled state of the aerosol generation device 1. Relative to the third partially assembled state, the device 1 additionally comprises the heating chamber 12. FIG. 5 illustrates a common line L along which all of the heating chamber 12, the first control circuitry 131 and the electrical power source 11 are arranged. In the fully assembled device according to the embodiment of FIG. 1, the mouth end 141 is also arranged on the common line L.

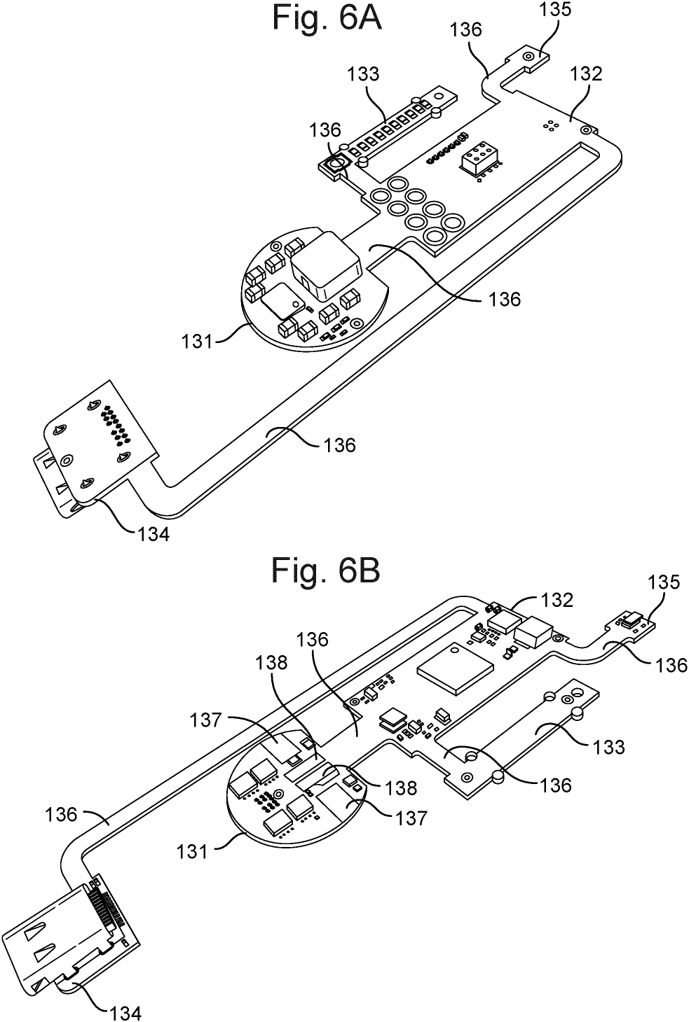

FIGS. 6A and 6B are schematic illustrations of first and second sides of control circuitry of the aerosol generation device. FIGS. 6A and 6B also illustrate an example of a form in which control circuitry for an aerosol generation device may be distributed on its own.

As shown in FIGS. 6A and 6B, in the embodiment of the figures, the control circuitry 13 comprises the first PCB 131, the second PCB 132, the third PCB 133, a fourth PCB 134 and a fifth PCB 135. The five PCBs are connected together by flexible PCB portions 136 which can contain electrical connections neatly and in preprinted form which can be easily assembled and folded to fit within the housing 14. Alternatively, any pair of PCBs may be connected by, for example, wires or tabs that are soldered to each board, or may be connected by spring contacts and/or card/slot connectors.

The first PCB 131 is, as described above, a power board for supplying power to the heating chamber 12 and for supplying power (in a smaller amount) for the rest of the control circuitry 13. Referring to FIG. 6B, the first PCB 131 comprises electrical contacts 137 for connections to the electrical power source 11 and electrical contacts 138 for connections to the heating chamber.

More specifically, in the embodiment of the figures, a first electrical contact 137 for the electrical power source 11 is adjacent to a first electrical contact 138 for the heating chamber 12 and a second electrical contact 137 for the electrical power source 11 is adjacent to a second electrical contact 138 for the heating chamber 12. The four contacts 137, 138 may be arranged in a row, as shown in FIG. 6B. This arrangement has the advantage of reducing the electrical path length within the first PCB 131 of the power supplied to the heating chamber 12, and thereby reducing the heat dissipated in the first PCB 131.

In alternative embodiments, a first electrical contact 137 for the electrical power source 11 may be directly connected to a first electrical contact 138 for the heating chamber 12. This has the effect that only one terminal of the supply from the electrical power source 11 to the heating chamber 12 is switchable, but simplifies construction by enabling merging of the electrical contacts to only three distinct contacts on the first PCB 131.

In further alternative embodiments, the first PCB 131 is a double-sided PCB comprising contacts on both sides (e.g. the side visible in FIG. 6A and the side visible in FIG. 6B). The electrical contacts 137 for the electrical power source 11 may be arranged on one side of the first PCB 131 that is to face the opposing end 142, and the electrical contacts 138 for the electrical power source 11 may be arranged on the other side of the first PCB 131 that is to face the mouth end 141. With this arrangement, no connections need to extend between the first PCB 131 and the power source frame 15, meaning that the first PCB 131 and power source frame 15 can provide a more effective thermal barrier.

The second PCB 132 is, in the embodiment if the figures, a main logical board which performs central control of the rest of the control circuitry 13. As shown in FIG. 6A, the second PCB additionally comprises electrical contacts for one or more temperature sensors arranged to sense a temperature of the electrical power source 11 or the heating chamber 12.

The third PCB 133 is a user interface board comprising one or more buttons, sliders and lights, or other input/output components, for providing a user interface through which the user can control the device 1 and know a state of the device 1. The contacts on the second PCB 132 may also be connected to one or more further I/O components, such as a tactile feedback element (e.g. vibrator).

The fourth PCB 134 is a charging board through which power may be supplied to recharge the electrical power source 11. In the embodiment of the figures, the fourth PCB 134 is connected to the second PCB 132, and power for recharging the electrical power source 11 passes through the main logical board. In other embodiments, the fourth PCB 134 may be additionally or alternatively connected to the first PCB 131 or directly to the electrical power source 11, so that recharging power is separated from the logical circuitry of the second PCB 132.

The fifth PCB 135 of the embodiment is a Hall sensor board. This is used together with a magnet in a lid at the mouth end 141 of the housing 14, to detect an open or closed state of the mouth end 141. The fifth PCB 135 may be omitted in many embodiments where such an open or closed state does not need to be detected.

The above-described arrangement of the heating chamber 12, the first control circuitry 131 and the electrical power source 11 can be achieved without requiring insulating frames 15, 16. For example, an internal surface of the housing 14 could be adapted to align the heating chamber 12, the first control circuitry 131 and the electrical power source 11 in this arrangement, when they are inserted into the housing 14 to assemble the device 1. In such embodiments, the first control circuitry 131 can be loose between the heating chamber 12 and the electrical power source 11 or can be held in a fixed position by some combination of the heating chamber 12, the electrical power source 11 and the housing 14. One embodiment is similar to the embodiment described above with reference to the figures, except the frames 15 and 16 are omitted.

Furthermore, the first PCB 131 may not be arranged transverse to the line between the electrical power source 11 and the heating chamber 12. Even when the first PCB 131 is arranged differently, its presence between the electrical power source 11 and the heating chamber 12 means that the electrical path from the electrical power source 11 and the heating chamber 12 can be shortened, although the first PCB may be less effective as a heat barrier in other arrangements.

Additionally, in some embodiments, the control circuitry 13 may be provided without the use of one or more PCBs. For example, the first control circuitry 131 may comprise only a mechanical switch, with a control arm extending between the exterior of the housing 14 and a set of electrical contacts located between the heating chamber 12 and the electrical power source 11. Other circuit components may be connected by wires rather than a printed circuit. Even in these embodiments, the control circuitry 13 is arranged such that an electrical path from the electrical power source 12 to the heating chamber 11 is shortened, and resistive losses in the electrical path are reduced.

In the above embodiment, the control circuitry 13 comprises a plurality of portions (first control circuitry 131, second control circuitry 132 etc.). In other embodiments, the second control circuitry 132 and so on may be omitted, for example in the previously described case where the control circuitry 13 consists of a simple switch. One embodiment is similar to the embodiment described with reference to the figures, but the second, third, fourth and fifth control circuitries 132-135 (second to fifth PCBs) are omitted along with the flexible PCB portions 136.

1. An aerosol generation device comprising:
an electrical power source;
a heating chamber operable to heat an aerosol substrate to generate an aerosol;
first control circuitry configured to control a supply of electrical power from the electrical power source to the heating chamber; and
a housing comprising a mouth end and an opposing end,
wherein the electrical power source, the heating chamber and the first control circuitry are arranged in an internal volume of the housing, the heating chamber being arranged between the first control circuitry and the mouth end, and the first control circuitry being arranged between the heating chamber and the electrical power source.

2. The aerosol generation device according to claim 1, wherein the mouth end, the heating chamber, the first control circuitry and the electrical power source are arranged along a common line.

3. The aerosol generation device according to claim 2, wherein the first control circuitry comprises a first PCB.

4. The aerosol generation device according to claim 3, wherein the first PCB is arranged in a plane transverse to the common line.

5. The aerosol generation device according to claim 3, wherein the first PCB comprises electrical contacts for connections to the electrical power source and electrical contacts for connections to the heating chamber.

6. The aerosol generation device according to claim 5, wherein, on a surface of the first PCB, a first electrical contact for the electrical power source is adjacent to a first electrical contact for the heating chamber and a second electrical contact for the electrical power source is adjacent to a second electrical contact for the heating chamber.

7. The aerosol generation device according to claim 6, wherein the first PCB is a double-sided PCB, and the electrical contacts for connections to the electrical power source are arranged on one side of the double-sided PCB and the electrical contacts for connections to the heating chamber are arranged on another side of the double-sided PCB.

8. The aerosol generation device according to claim 5 , wherein, in the first PCB, a first electrical contact for the electrical power source is directly connected to a first electrical contact for the heating chamber or a second electrical contact for the electrical power source is directly connected to a second electrical contact for the heating chamber.

9. The aerosol generation device according to claims 3, wherein the first PCB is arranged as a thermal barrier between the heating chamber and the electrical power source.

10. The aerosol generation device according to claim 1, further comprising a heating chamber frame configured to support the heating chamber, and a power source frame configured to support the electrical power source.

11. The aerosol generation device according to claim 10, wherein the first control circuitry is supported between the heating chamber frame and the power source frame.

12. The aerosol generation device according to claim 1, further comprising second control circuitry, wherein the first control circuitry is configured to support a higher power than the second control circuitry, the first control circuitry being configured to communicate with the second control circuitry using logical signalling.

13. The aerosol generation device according to claim 12, wherein the second control circuitry comprises a second PCB.

14. The aerosol generation device according to claim 13, wherein the first control circuitry comprises a first PCB, and the second PCB is connected to the first PCB by a flexible PCB portion.

15. The aerosol generation device according to claim 12, wherein the second control circuitry is arranged alongside the heating chamber.

16. Control circuitry for an aerosol generation device comprising an electrical power source and a heating chamber operable to heat an aerosol substrate to generate an aerosol, the control circuitry comprising:
a first PCB configured to control a supply of electrical power from the electrical power source to the heating chamber, wherein the first PCB comprises electrical contacts for connections to the electrical power source and electrical contacts for connections to the heating chamber; and
a second PCB, wherein the first PCB is configured to support a higher power than the second PCB, the first PCB being configured to communicate with the second PCB using logical signalling.

17. The control circuitry according to claim 16, wherein the second PCB is connected to the first PCB by a flexible PCB portion.

18. The control circuitry according to claim 16, wherein the first PCB is a double-sided PCB comprising contacts on both sides.

19. The control circuitry according to claim 16, wherein the second PCB comprises a main logical board configured to perform central control of the rest of the control circuitry.

20. The control circuitry according to claim 19, further comprising a third PCB which is a user interface board.

21. The control circuitry according to claim 20, further comprising a fourth PCB comprising a charging board through which power may be supplied to recharge the electrical power source.

22. The control circuitry according to claim 21, further comprising a fifth PCB which comprises a Hall sensor.

23. The control circuitry according to claim 22, wherein the second PCB is connected to the first, third, fourth and fifth PCBs by flexible portions.
